(19) United States
(12) Patent Application Publication
(10) Pub. No.: US 2016/0027758 A1
(43) Pub. Date: Jan. 28, 2016

(54) SEMICONDUCTOR DEVICE

(71) Applicant: PS4 LUXCO S.A.R.L., Luxembourg (LU)

(72) Inventors: Mitsuaki Katagiri, Tokyo (JP); Yu Hasegawa, Tokyo (JP)

(73) Assignee: PS4 LUXCO S.A.R.L., Luxembourg (LU)

(21) Appl. No.: 14/774,548

(22) PCT Filed: Mar. 10, 2014
(86) PCT No.: PCT/JP2014/056186

§ 371 Date: Sep. 10, 2015

(30) Foreign Application Priority Data
Mar. 13, 2013 (JP) 2013-050405

(51) Int. Cl. H01L 23/00

(52) U.S. Cl. CPC H01L 24/49; H01L 24/09; H01L 24/14; H01L 24/33; H01L 2224/0235; H01L 2224/14051; H01L 2224/141

(57) ABSTRACT

[Problem] To provide a semiconductor device with a wafer level package structure that allows for probing while reducing the area occupied by the pad electrodes. [Solution] In the present invention, the following are provided: a semiconductor chip (100) that has first and second pad electrodes (120a, 120b) disposed on the main surface thereof; insulating films (310, 330) that cover the main surface of the semiconductor chip (100); a rewiring layer (320) that is disposed between the insulating films (310, 330); and a plurality of external terminals (340) disposed on the top of the insulating film (330). The plane size of the first pad electrode (120a) and the second pad electrode (120b) differ from one another, and the first pad electrode (120a) and the second pad electrode (120b) are connected to any of the plurality of external terminals (340) via the rewiring layer (320). According to the present invention, because the pad electrodes (120a, 120b) of different sizes are intermixed, probing can be easily performed while reducing the area occupied by the pad electrodes.

### TECHNICAL FIELD

The present invention relates to a semiconductor device, and more particularly to a semiconductor device having pad columns arranged in a center portion thereof.

### BACKGROUND

Many semiconductor devices include a semiconductor chip and a package that houses the semiconductor chip. Typical packages include a rigid package substrate in which pad electrodes formed on the semiconductor chip are connected to external terminals via a wiring layer (or a multilevel wiring layer) formed on the package substrate. Meanwhile, there are also packages known as wafer-level packages in which a rigid substrate is not used and a rewiring layer is formed directly on the principal surface of the semiconductor chip as part of the same process used to manufacture the semiconductor chip itself (see Patent Document 1). In both package types, pad columns are typically formed in a center portion of the chip to improve signal characteristics, particularly in semiconductor devices used in memory devices or the like.

### PATENT DOCUMENT

Patent Document 1: Japanese Patent Application Laid-Open Publication No. 2007-157879

### SUMMARY OF THE INVENTION

### Problems to be Solved by the Invention

In these types of semiconductor devices, in which pad columns are formed in the center portion of the chip, all of the pads are concentrated at the center portion. Therefore, while impedance is low at the center portion of the chip, in the surrounding areas the impedance increases as the distance from the center portion increases.

### Means for Solving the Problems

A semiconductor device of the present invention includes: a semiconductor chip; a plurality of first pad electrodes formed running in a first direction through a center portion of a principal surface of the semiconductor chip; and a plurality of second pad electrodes formed on the principal surface of the semiconductor chip between a pad column formed by the first pad electrodes and a side of the semiconductor chip, and is characterized in that the first pad electrodes and the second pad electrodes have a different planar size.

### Effects of the Invention

The present invention makes it possible to reduce wiring impedance and improve signal integrity throughout the chip by forming pads both in the center portion of the chip as well as in the surrounding areas.

### BRIEF DESCRIPTION OF THE DRAWINGS

FIG. 1 is a cross-sectional view schematically illustrating a configuration of a semiconductor device 10 as claimed in a first preferred embodiment of the present invention.

FIG. 2 is a plan view schematically illustrating a layout for pad electrodes 120.

FIG. 3 is a plan view schematically illustrating a layout for some of the rewiring layers 320 of a rewiring structure 300.

FIG. 4 is a cross-sectional view schematically illustrating a cross section taken along line A-A′ in FIG. 3.

FIG. 5 is a circuit diagram illustrating an example of a connection configuration between an internal circuit 130 of a semiconductor chip 100 and rewiring layers 321 to 326.

FIG. 6 is a cross-sectional view schematically illustrating a configuration of a semiconductor device 20 as claimed in a second preferred embodiment of the present invention.

FIG. 7 is a top view of the semiconductor device 20.

FIG. 8 is a cross-sectional view schematically illustrating a configuration of a semiconductor device 30 as claimed in a third preferred embodiment of the present invention.

FIG. 9 illustrates a layout of external terminals 260 formed on the other surface 210b of an insulating base material 210.

FIG. 10 is a plan view schematically illustrating a layout for bump electrodes 110 formed on a semiconductor chip 103.

FIG. 11(a) is a cross-sectional view of a bump electrode 110a, and FIG. 11(b) is a plan view illustrating a footprint of the bump electrode 110a.

FIG. 12(a) is a cross-sectional view of a bump electrode 110b, and FIG. 12(b) is a plan view illustrating a footprint of the bump electrode 110b.

FIG. 13 is a cross-sectional view of a bump electrode 110c.

FIG. 14 illustrates planar shapes for a bump electrode 110a. FIG. 14(a) illustrates a planar shape of a bump electrode 110a used to supply power, and FIG. 14(b) illustrates a planar shape of a bump electrode 110a for signal input/output.

### DETAILED DESCRIPTION OF EMBODIMENTS

Preferred embodiments of the present invention will be described in detail below with reference to the attached drawings.

FIG. 1 is a cross-sectional view schematically illustrating a configuration of a semiconductor device 10 as claimed in a first preferred embodiment of the present invention.

As illustrated in FIG. 1, the semiconductor device 10 as claimed in the present embodiment includes a semiconductor chip 100 and a rewiring structure 300 formed on the principal surface thereof. The semiconductor device 10 of the present embodiment is a so-called wafer-level package (WLP) and does not include a rigid insulating base material.

The semiconductor chip 100 is a single-chip device in which a large number of elements such as transistors are formed on a semiconductor substrate made from silicon (Si) or the like. The type of the semiconductor chip 100 is not particularly limited. The semiconductor chip 100 may be a memory device such as a dynamic random access memory (DRAM) device, a logic device such as a central processing unit (CPU), or an analog device such as a sensor, for example. A plurality of pad electrodes 120 (120a, 120b) are formed on the principal surface of the semiconductor chip 100. Here, the “principal surface” of the semiconductor chip 100 refers to the surface of an interlayer insulating film covering the surface of the silicon substrate on which the transistors or the like are formed. In other words, between the principal surface of the semiconductor chip 100 and the surface of the silicon substrate, there are a plurality of interlayer insulating films and wiring layers formed between these interlayer insulating films. These interlayer insulating films and wiring layers are not shown in the figure.

A rewiring structure 300 includes: a first insulating film 310 covering the principal surface of the semiconductor chip 100; rewiring layers 320 formed on the surface of the first insulating film 310; a second insulating film 330 covering the rewiring layers 320; and external terminals 340 formed on the surface of the second insulating film 330. A plurality of through-holes 310a that expose the pad electrodes 120 are formed in the first insulating film 310, and the pad electrodes 120 are electrically connected to the rewiring layers 320 via these through-holes 310a. Similarly, a plurality of through-holes 330a that expose the rewiring layers 320 are formed in the second insulating film 330, and the rewiring layers 320 are electrically connected to the external terminals 340 via these through-holes 330a. The rewiring layers 320 convert the pitch of the pad electrodes 120 to the pitch of the external terminals 340.

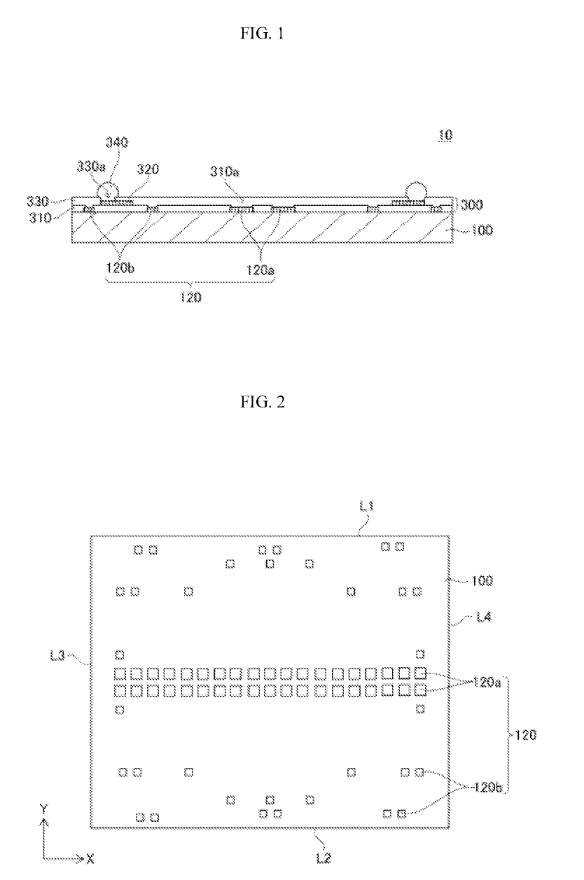

FIG. 2 is a plan view schematically illustrating a layout for the pad electrodes 120 formed on the semiconductor chip 100.

As illustrated in FIG. 2, the plurality of pad electrodes 120 includes first pad electrodes 120a and second pad electrodes 120b. The first pad electrodes 120a are arranged into two columns running in the X direction through the substantially center portion of the semiconductor chip 100 in the Y direction. More specifically, the principal surface of the semiconductor chip 100 has first and second sides L1 and L2 that run parallel to the X direction as well as third and fourth sides L3 and L4 that run parallel to the Y direction. The first pad electrodes 120a are arranged into two columns running in the X direction from the substantially center portion of the third side L3 in the Y direction to the substantially center portion of the fourth side L4 in the Y direction. The first pad electrodes 120a are used for signal input/output or to supply a voltage from an external power source.

Meanwhile, the second pad electrodes 120b are arranged at arbitrary positions on the principal surface of the semiconductor chip 100. The second pad electrodes 120b are used primarily to supply a voltage from an external power source, but as will be described in more detail later, the second pad electrodes 120b can also be used as a bypass for a voltage from an internal power source. As illustrated in FIG. 2, the planar size of each first pad electrode 120a is greater than the planar size of each second pad electrode 120b.

The first pad electrodes 120a have a larger area for two reasons. First, this makes it possible to connect the probes of a testing device to the pads when testing the wafer. Second, when using other construction techniques (such as wire bonding, for example), an area large enough to make a connection is required. In contrast, the probes of a testing device do not need to be connected to the second pad electrodes 120b during testing of the wafer, and therefore the second pad electrodes 120b can have a smaller area. Moreover, as illustrated in FIG. 2, the second pad electrodes 120b are arranged in arbitrary regions of the semiconductor chip 100 other than the main pad area. This is partially because it can be difficult to allocate space for larger pads in the corresponding wiring layers.

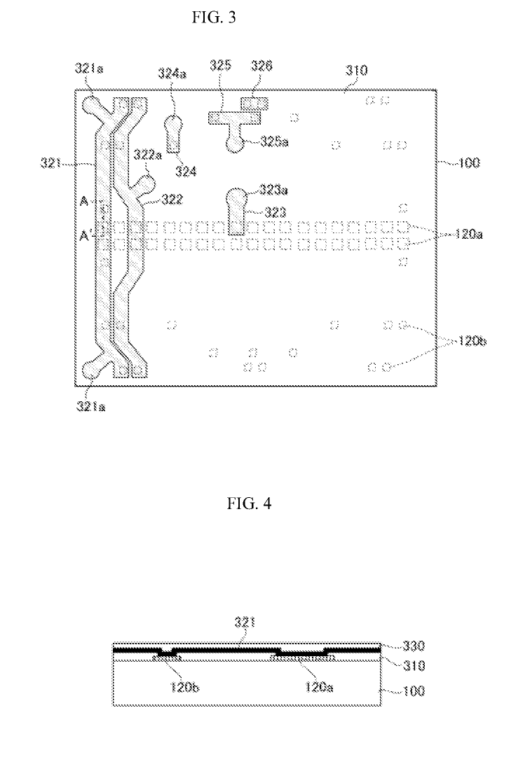

FIG. 3 is a plan view schematically illustrating a layout for some of the rewiring layers 320 of a rewiring structure 300. Moreover, FIG. 4 is a cross-sectional view schematically illustrating a cross section taken along line A-A′ in FIG. 3.

FIG. 3 only depicts six types of rewiring layers 321 to 326 out of the large overall number of rewiring layers 320. The dotted lines in FIG. 3 represent the first and second pad electrodes 120a and 120b. Furthermore, the second insulating film 330 and the external terminals 340, which are positioned in the uppermost layer, are not depicted in FIG. 3.

The rewiring layer 321 connects two of the first pad electrodes 120a and six of the second pad electrodes 120b to one another. The rewiring layer 321 is connected to the external terminals 340 via terminal regions 321a. The terminal regions 321a are formed at different planar positions than any of the corresponding pad electrodes 120. Therefore, these pad electrodes 120a and 120b as well as the external terminals 340 are each formed at different planar positions relative to one another. This rewiring layer 321 is used to supply a ground voltage VSS to the semiconductor chip 100, for example. Therefore, when a ground voltage VSS is supplied via these external terminals 340 and terminal regions 321a, the ground voltage VSS is applied to each of these two first pad electrodes 120a and six second pad electrodes 120b. Furthermore, because the second pad electrodes 120b are formed in arbitrary areas of the principal surface of the semiconductor chip 100 other than the main pad area, the ground voltage VSS can be supplied directly from these arbitrary areas. This makes it possible to reduce in-plane variations in the ground voltage VSS within the semiconductor chip 100. Moreover, when testing the wafer, the tips of the probes of the testing device can be touched to these first pad electrodes 120a to supply a ground voltage VSS to the semiconductor chip 100.

Similarly, the rewiring layer 322 connects two of the first pad electrodes 120a and four of the second pad electrodes 120b to one another. The rewiring layer 322 is connected to one of the external terminals 340 via a terminal region 322a. The terminal region 322a is formed at a different planar position than any of the corresponding pad electrodes 120a and 120b. Therefore, these pad electrodes 120a and 120b as well as the external terminal 340 are each formed at different planar positions relative to one another. This rewiring layer 322 is used to provide a supply voltage VDD to the semiconductor chip 100, for example. Therefore, when a supply voltage VDD is supplied via this external terminal 340 and terminal region 322a, the supply voltage VDD is applied to each of these two first pad electrodes 120a and four second pad electrodes 120b. Furthermore, because the second pad electrodes 120b are formed in arbitrary areas of the principal surface of the semiconductor chip 100 other than the main pad area, the supply voltage VDD can be supplied directly from these arbitrary areas. This makes it possible to reduce in-plane variations in the supply voltage VDD within the semiconductor chip 100. Moreover, when testing the wafer, the tips of the probes of the testing device can be touched to these first pad electrodes 120a to provide a supply voltage VDD to the semiconductor chip 100.

Meanwhile, the rewiring layer 323 is connected to a single first pad electrode 120a. The rewiring layer 323 is connected to one of the external terminals 340 via a terminal region 323a. The terminal region 323a is formed at a different planar position than the corresponding pad electrode 120a. Therefore, this pad electrode 120a and the external terminal 340 are formed at different planar positions relative to one another. This rewiring layer 323 is used for signal input/output. When inputting and outputting signals to and from the semiconductor chip 100, it is not necessary to use a plurality of the pad electrodes 120. Therefore, this type of rewiring layer 323 is used for signal input/output. Moreover, when testing the wafer, the tips of the probes of the testing device can be touched to this first pad electrode 120a to input a signal output from the testing device to the semiconductor chip 100 or to input a signal output from the semiconductor chip 100 to the testing device.

Furthermore, the rewiring layer 324 is connected to a single second pad electrode 120b. The rewiring layer 324 is connected to one of the external terminals 340 via a terminal region 324a. The terminal region 324a is formed at a different planar position than the corresponding pad electrode 120b. Therefore, this pad electrode 120b and the external terminal 340 are formed at different planar positions relative to one another. This rewiring layer 324 can also be used for signal input/output. However, because the second pad electrode 120b has a small planar size, the tips of the probes of the testing device cannot be touched to the second pad electrode 120b. Therefore, when testing the wafer, a signal terminal that does not need to be connected to the testing device can be connected to the rewiring layer 324.

Similarly, the rewiring layer 325 is connected to two of the second pad electrodes 120b. The rewiring layer 325 is connected to one of the external terminals 340 via a terminal region 325a. This rewiring layer 325 can also be used to supply a ground voltage VSS or a supply voltage VDD. However, because the second pad electrodes 120b have a small planar size, the tips of the probes of the testing device cannot be touched to these second pad electrodes 120b. Therefore, when testing the wafer, a power supply terminal that does not need to be connected to the testing device can be connected to the rewiring layer 325.

Furthermore, the rewiring layer 326 is connected to two of the second pad electrodes 120b. However, the rewiring layer 326 is not connected to any of the external terminals 340. This rewiring layer 326 is formed in order to be able to bypass internal signals in the semiconductor chip 100 or to be able to bypass a voltage from an internal power source in the semiconductor chip 100. The rewiring layer 326 is not connected to an external terminal 340, and the second pad electrodes 120b corresponding to the rewiring layer 326 cannot be touched with the probes. However, this is not a problem because there is no need to output internal signals or a voltage from an internal power source to outside of the semiconductor chip 100. Moreover, the rewiring layer 326 is formed on the rewiring structure 300 side of the semiconductor chip 100 and therefore has a much greater film thickness than the wires formed inside of the semiconductor chip 100. As a result, the rewiring layer 326 exhibits an extremely low resistance and can be used to bypass internal signals and a voltage from an internal power source in order to improve the transmission speed of internal signals and greatly reduce decreases in the magnitude of the voltage from the internal power source.

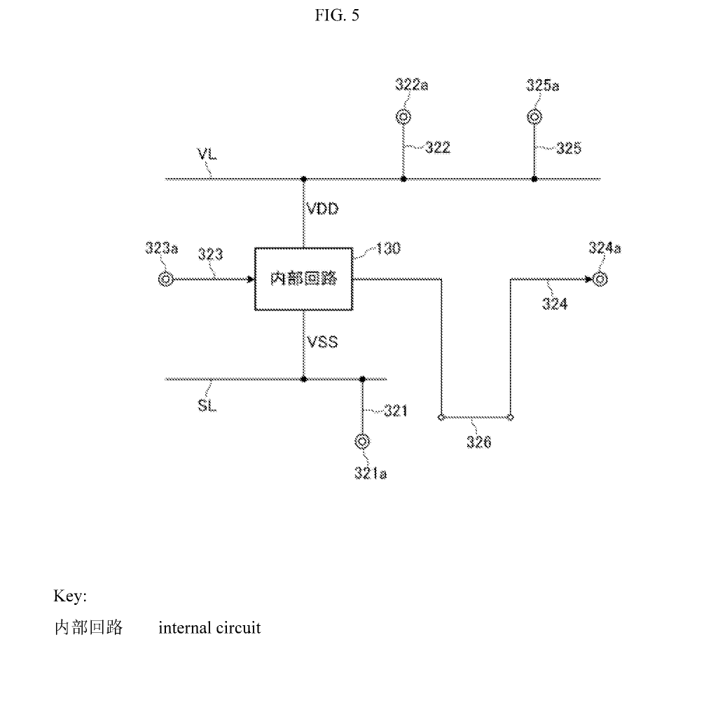

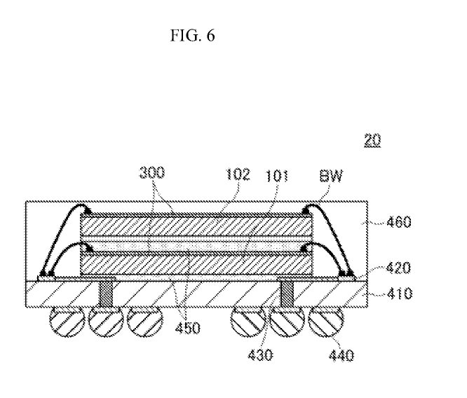

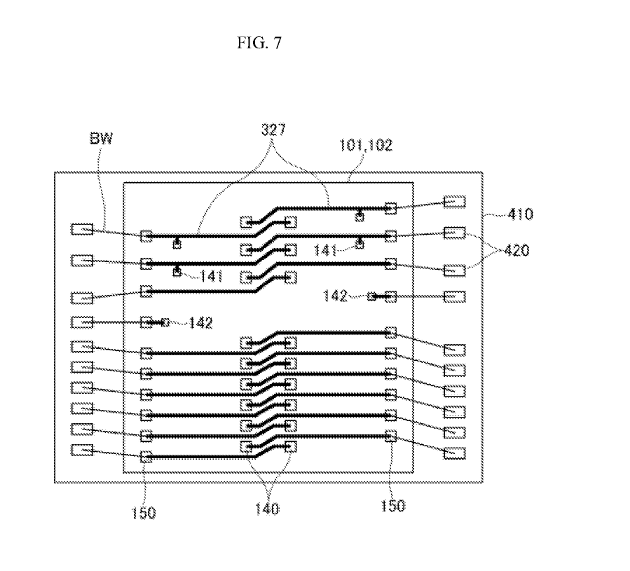

FIG. 5 is a circuit diagram illustrating an example of a connection configuration between an internal circuit 130 of a semiconductor chip 100 and the rewiring layers 321 to 326.

In the example shown in FIG. 5, the semiconductor chip 100 includes an internal circuit 130. The internal circuit 130 is operated by the voltage between a supply voltage VDD supplied via a supply line VL and a ground voltage VSS supplied via a ground line SL. As illustrated in FIG. 5, the supply line VL is connected to the terminal region 322a via the rewiring layer 322 and is also connected to the terminal region 325a via the rewiring layer 325. Meanwhile, the ground line SL is connected to the terminal region 321a via the rewiring layer 321. An input signal is input to the internal circuit 130 from the terminal region 323a via the rewiring layer 323. Furthermore, the output signal from the internal circuit 130 is sent to the terminal region 324a via the rewiring layers 326 and 324.

As described above, in the semiconductor device 10 of the present embodiment, the first pad electrodes 120a (which need to be probed when testing the wafer) are designed to have a large planar size, and the second pad electrodes 120b (which do not need to be probed during testing) are designed to have a small planar size. This makes it possible to make probing during the testing process easier while simultaneously limiting the area occupied by the pad electrodes.

Moreover, the second pad electrodes 120b that are used to supply power are connected to the corresponding first pad electrodes 120a via the rewiring layers 321 and 322, for example. Therefore, positioning these second pad electrodes 120b in arbitrary areas makes it possible to reduce in-plane variations in the ground voltage VSS and the supply voltage VDD.

Furthermore, creating a short-circuit between several of the second pad electrodes 120b via the rewiring layer 326 makes it possible to improve the transmission speed of internal signals that do not need to be output outside of the semiconductor device 10 as well as to greatly reduce decreases in the magnitude of the voltage from an internal power source.

FIG. 6 is a cross-sectional view schematically illustrating a configuration of a semiconductor device 20 as claimed in a second preferred embodiment of the present invention.

As illustrated in FIG. 6, a semiconductor device 20 as claimed in the present embodiment includes two semiconductor chips 101 and 102 mounted on a wiring substrate 410. The semiconductor chips 101 and 102 are both mounted on the wiring substrate 410 in a face up orientation, and therefore the rewiring structures 300 of the semiconductor chips 101 and 102 are disposed on the side of the each semiconductor chip opposite to the wiring substrate 410 (that is, on the top side). In the present embodiment, bonding pads are formed on the rewiring structures 300. The bonding pads of the rewiring structures 300 are connected to substrate electrodes 420 formed on the wiring substrate 410 via bonding wires BW. The substrate electrodes 420 are connected to external terminals 440 formed on the rear surface via through-electrodes 430 formed going through the wiring substrate 410. Adhesive layers 450 are formed between the wiring substrate 410 and the semiconductor chip 101 as well as between the semiconductor chip 101 and the semiconductor chip 102. Furthermore, a sealing resin 460 that seals in the semiconductor chips 101 and 102 is formed on the surface of the wiring substrate 410.

FIG. 7 is a top view of the semiconductor device 20. Note that in order to make FIG. 7 easier to view, the sealing resin 460 is not depicted.

As illustrated in FIG. 7, the semiconductor chips 101 and 102 used in the present embodiment each include: pad electrodes 140 arranged in two columns running in one direction through the substantially center portion of the chip; bonding pads 150 arranged running in the same direction along the edges of the chip; and rewiring layers 327 that connect the pad electrodes 140 and the bonding pads 150 to one another. The pad electrodes 140 only have to be large enough to make it possible to connect the rewiring layers 327 thereto and are therefore small in size. In contrast, the bonding pads 150 have to be large enough to make it possible to connect the bonding wires BW thereto and are therefore larger in size. Furthermore, the semiconductor chips 101 and 102 each include small pads 141 and 142 that are smaller than the pad electrodes 140. These small pads 141 and 142 correspond to the pad electrodes 120b in FIGS. 1 to 4. The small pads 141 and 142 are arranged primarily between the pad electrodes 140 and the bonding pads 150, and each small pad 141 and 142 is connected to one of the rewiring layers 327. However, while the small pads 141 are connected to rewiring layers 327 that are connected to both the pad electrodes 140 and the bonding pads 150, the small pads 142 are connected to rewiring layers 327 that are only connected to the bonding pads 150 and are not connected to the pad electrodes 140.

In this way, in contrast with the semiconductor device 10 as claimed in Embodiment 1 as described above, in the semiconductor device 20 of the present embodiment the pad electrodes 140 arranged in the center portion of the chips are smaller than the bonding pads 150 arranged along the edges of the chips. FIG. 7 depicts so-called two center pad column chips in which the pad electrodes 140 are arranged in two columns running in one direction through the substantially center portion of the chips as an example. However, the chips may also be so-called single center pad column chips in which the pad electrodes 140 are arranged in a single column running in one direction through the substantially center portion of the chips.

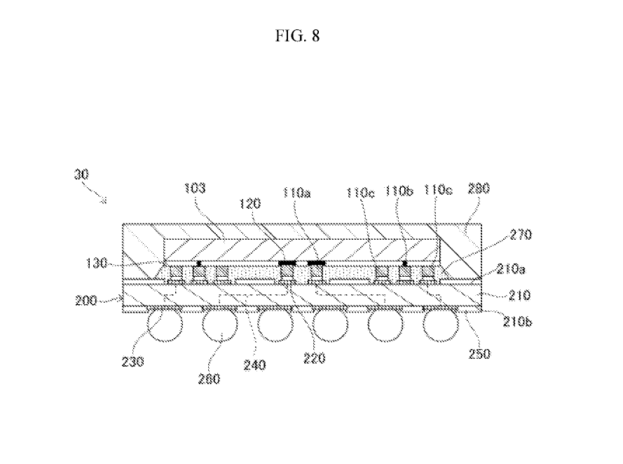

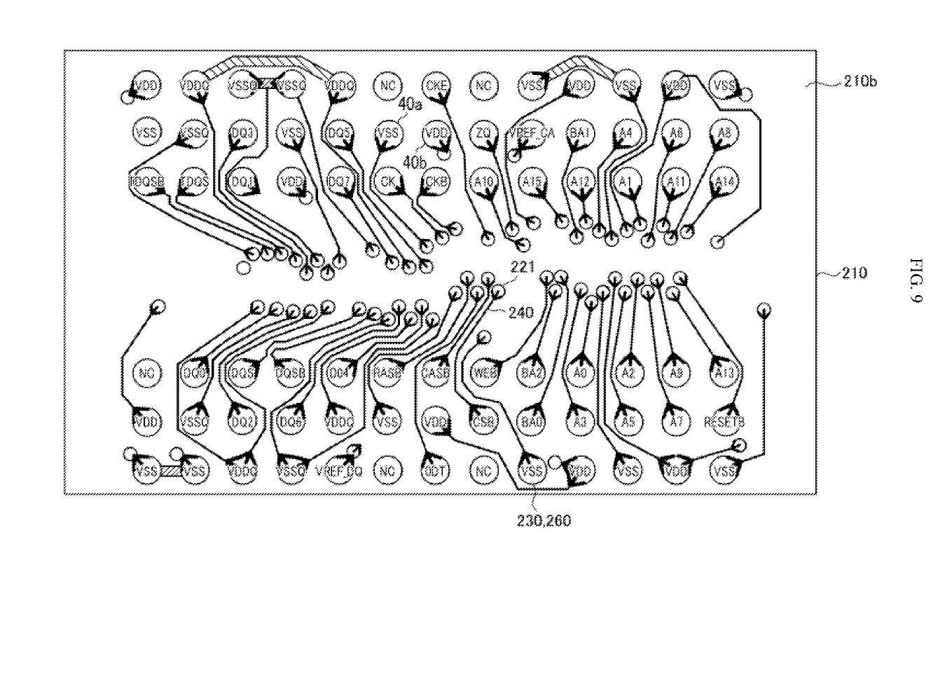

FIG. 8 is a cross-sectional view schematically illustrating a configuration of a semiconductor device 30 as claimed in a third preferred embodiment of the present invention.

As illustrated in FIG. 8, a semiconductor device 30 as claimed in the present embodiment includes a semiconductor chip 103 and a wiring substrate 200 on which the semiconductor chip 103 is flip chip-mounted.

The wiring substrate 200 is a circuit board that functions as a wiring structure and includes: an insulating base material 210 made from a glass epoxy material 0.2 mm in thickness, for example; connector electrodes 220 formed on one surface 210a of the insulating base material 210; and a land pattern 230 formed on the other surface 210b of the insulating base material 210. The connector electrodes 220 are connected to the land pattern 230 via a wiring pattern 240 formed on the insulating base material 210. The wiring pattern 240 may be formed on either surface of the insulating base material 210 or inside the insulating base material 210. On both surfaces of the insulating base material 210, the portions where the connector electrodes 220 or the land pattern 230 are not formed are covered by solder resist 250. The connector electrodes 220 contact bump electrodes 110 formed on the semiconductor chip 100. Moreover, the land pattern 230 is connected to external terminals 260 made from solder balls. Furthermore, an underfill 270 is filled in between the wiring substrate 200 and the semiconductor chip 100, and a sealing resin 280 is formed covering the semiconductor chip 100.

FIG. 9 illustrates a layout of external terminals 260 formed on the other surface 210b of the insulating base material 210. As illustrated in FIG. 9, the wiring pattern 240 is formed on the other surface 210b of the insulating base material 210 and connects through-hole conductors 221 to the land pattern 230 (that is, to the external terminals 260).

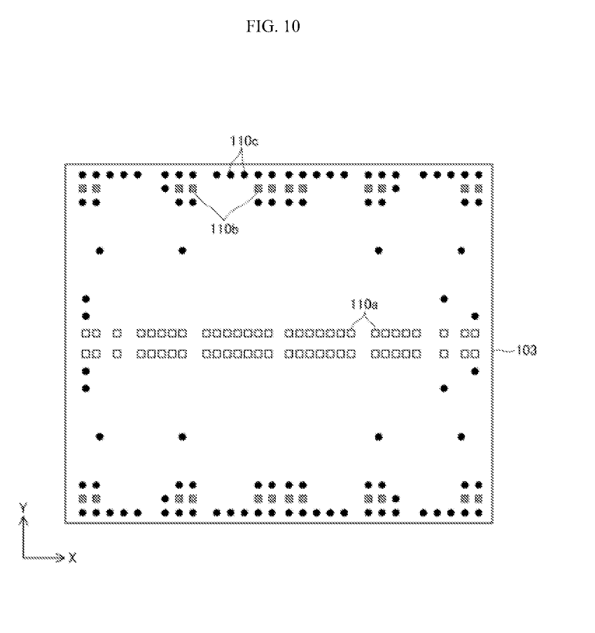

FIG. 10 is a plan view schematically illustrating a layout for the bump electrodes 110 formed on the semiconductor chip 103.

As illustrated in FIG. 10, bump electrodes 110a are arranged into two columns running in the X direction through the substantially center portion of the semiconductor chip 100 in the Y direction. The bump electrodes 110a are used for signal input/output or to supply a voltage from an external power source.

Meanwhile, bump electrodes 110b and 110c are arranged around the peripheral region of the semiconductor chip 100. The bump electrodes 110b are used to supply a voltage from an external power source and to increase the strength of the bond between the semiconductor chip 103 and the wiring substrate 200. In other words, because the semiconductor chip 103 that is made from silicon or the like and the wiring substrate 200 that is made from a resin or the like have very different coefficients of thermal expansion, temperature changes may cause the wiring substrate 200 to warp and thereby cause the semiconductor chip 103 to separate from the wiring substrate 200. To prevent this, the bump electrodes 110b are arranged around the peripheral region of the semiconductor chip 103 (which is particularly prone to separation) in order to increase the bond strength between the semiconductor chip 103 and the wiring substrate 200. Moreover, the bump electrodes 110c are dummy electrodes and are only used to increase the bond strength.

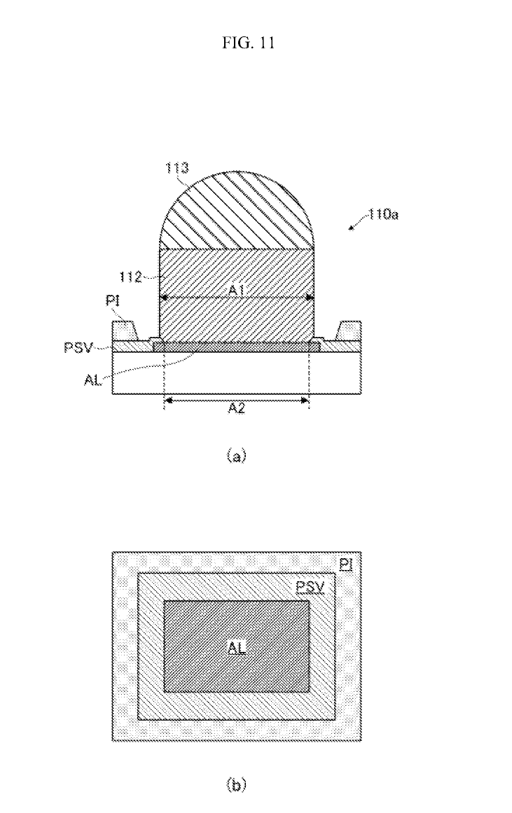

FIG. 11(a) is a cross-sectional view of one of the bump electrodes 110a, and FIG. 11(b) is a plan view illustrating a footprint of the bump electrode 110a.

As illustrated in FIGS. 11(a) and 11(b), the bump electrode 110a is formed on the exposed portion of a wiring layer AL formed on the semiconductor chip 103. Except for the exposed portion, the wiring layer AL is covered by a passivation film PSV, and the passivation film PSV is further covered by a protective film PI made from polyimide or the like. The bump electrode 110a includes a pillar portion 112 that covers the exposed portion of the wiring layer AL and a solder layer 113 formed on the top end face of the pillar portion 112. The pillar portion 112 is made from Cu, for example. The diameter of the bump electrode 110a is A1, and the diameter of the exposed portion of the wiring layer AL is A2, where A2<A1.

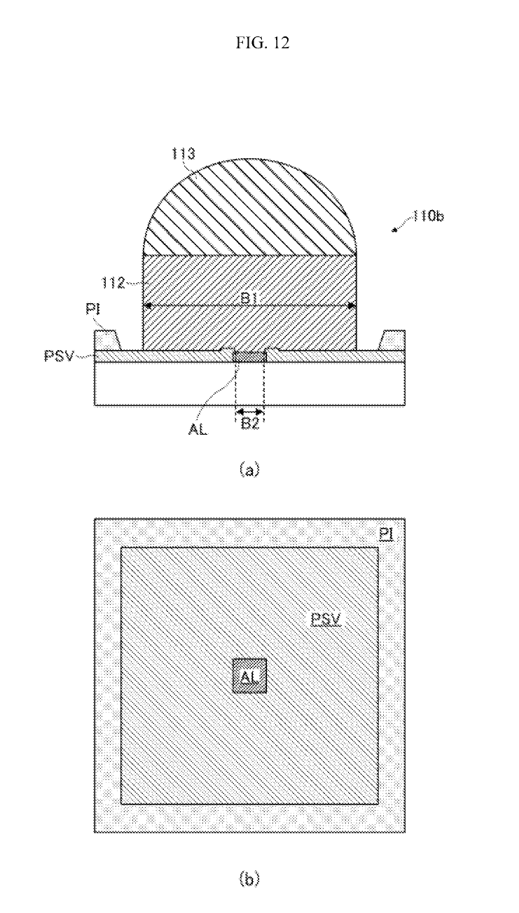

FIG. 12(a) is a cross-sectional view of one of the bump electrodes 110b, and FIG. 12(b) is a plan view illustrating a footprint of the bump electrode 110b. As illustrated in FIGS. 12(a) and 12(b), the bump electrode 110b is also formed covering an exposed portion of a wiring layer AL. However, the diameter B1 of the bump electrode 110b is greater than A1, and the diameter B2 of the exposed portion of the wiring layer AL is less than A2. The reason that the diameter B2 of the exposed portion of the wiring layer AL corresponding to the bump electrode 110b is small is because the bump electrodes 110b are not formed in the so-called main paid region of the chip but rather in a region of the chip in which a memory cell array or the like is typically formed and in which it is more difficult to allocate space for a wiring layer having a larger cross-sectional area such as that shown in FIG. 11(b).

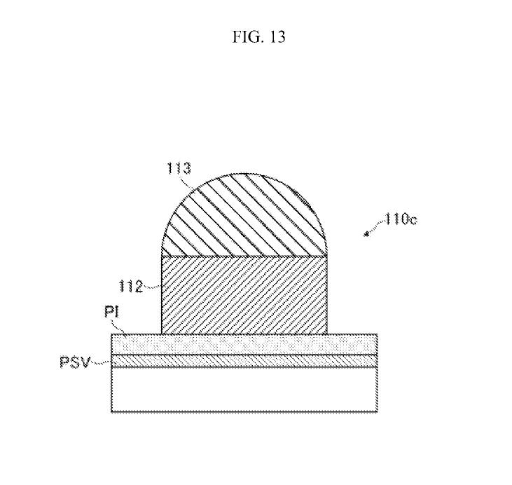

FIG. 13 is a cross-sectional view of a bump electrode 110c. The bump electrodes 110c are dummy bump electrodes, and therefore, as illustrated in FIG. 13, each bump electrode 110c is formed directly on the surface of the protective film PI. Therefore, the bump electrodes 110c are not connected to a wiring layer AL. The diameter of the bump electrodes 110c may be approximately equal to the diameter A1 of the bump electrodes 110a.

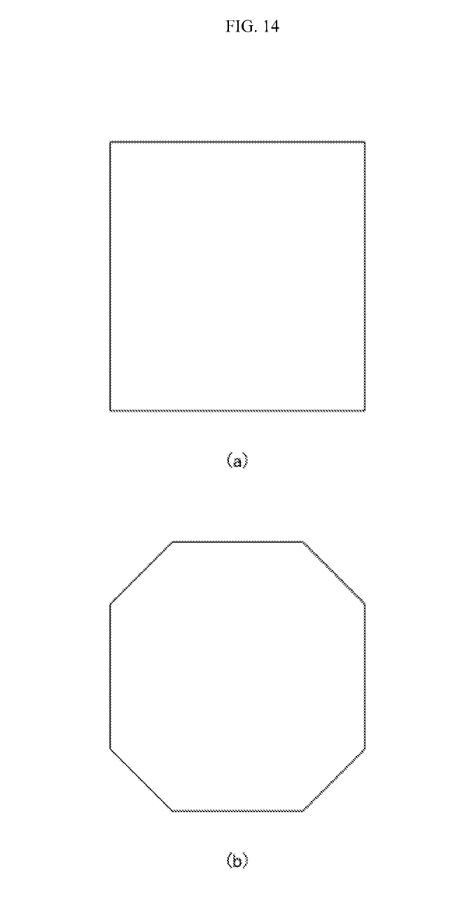

FIG. 14 illustrates planar shapes for the bump electrodes 110a. FIG. 14(a) illustrates a planar shape of a bump electrode 110a used to supply power, and FIG. 14(b) illustrates a planar shape of a bump electrode 110a for signal input/output. As illustrated in FIG. 14, bump electrodes 110a that are used to supply power have a square planar shape, and bump electrodes 110a that are used for signal input/output have an octagonal planar shape. This is because maximizing the planar size of the bump electrodes 110a used to supply power decreases impedance and because reducing the area of the bump electrodes 110a used for signal input/output prevents an increase in impedance due to the so-called skin effect.

Preferable embodiments of the present invention were described above. However, the present invention is not limited to these embodiments. Various modifications can be made without departing from the spirit of the present invention, and such modifications are included within the scope of the present invention.

### DESCRIPTION OF REFERENCE CHARACTERS

10, 20, 30 semiconductor device
100-103 semiconductor chip
110, 110a-110c bump electrode
112 pillar portion
113 solder layer
120, 120a, 120b pad electrode
130 internal circuit
140 pad electrode
150 bonding pad
200 wiring substrate
210 insulating base material
210a, 210b surface of insulating base material
220 connector electrode
221 through-hole conductor
230 land pattern
240 wiring pattern
250 solder resist
260 external terminal
270 underfill
280 sealing resin
300 rewiring structure
310, 330 insulating film
310a, 330a through-hole
320-327 rewiring layer
321a-326a terminal region
340 external terminal
410 wiring substrate
420 substrate electrode
430 through-electrode
440 external terminal
450 adhesive layer
460 sealing resin
AL wiring layer
BW bonding wire
L1-L4 side of semiconductor chip
PI protective film
PSV passivation film
SL ground line
VL supply line

1. A semiconductor device, comprising:
a semiconductor chip;
a plurality of first pad electrodes formed running in a first direction through a center portion of a principal surface of the semiconductor chip; and
a plurality of second pad electrodes formed on the principal surface of the semiconductor chip between a pad column formed by the first pad electrodes and a side of the semiconductor chip,
wherein the first pad electrodes and the second pad electrodes have a different planar size.

2. The semiconductor device as claimed in claim 1, wherein the first pad electrodes supply a first power source voltage, and the second pad electrodes supply a second power source voltage.

3. The semiconductor device as claimed in claim 2, wherein the first pad electrodes and the second pad electrodes both supply a same power source voltage.

4. The semiconductor device as claimed in claim 1, further comprising an internal circuit formed inside the semiconductor chip, wherein the first pad electrodes and the second pad electrodes are connected to power lines that supply a power source voltage to the internal circuit.

5. The semiconductor device as claimed in claim 1, further comprising:
a plurality of insulating films covering the principal surface of the semiconductor chip;
a rewiring layer formed between the insulating films; and
a plurality of external terminals formed on the insulating films,
wherein the first and second pad electrodes are each electrically connected to one of the external terminals via the rewiring layer.

6. The semiconductor device as claimed in claim 5, wherein the plurality of external terminals includes first external terminals and second external terminals, and the first and second pad electrodes are connected, respectively, to the first and second external terminals via the rewiring layer.

7. The semiconductor device as claimed in claim 6, wherein the first pad electrodes and the first external terminals have different planar positions, and the second pad electrodes and the second external terminals have different planar positions.

8. The semiconductor device as claimed in claim 5, wherein the plurality of external terminals includes third external terminals, and the first and second pad electrodes are both connected to the third external terminals via the rewiring layer.

9. The semiconductor device as claimed in claim 8, wherein the first pad electrodes and the third external terminals have different planar positions, and the second pad electrodes and the third external terminals have different planar positions.

10. The semiconductor device as claimed in claim 5, wherein the second pad electrodes have a larger planar size than the first pad electrodes, and the second pad electrodes are used to supply power.

11. The semiconductor device as claimed in claim 5, wherein the semiconductor chip further includes third and fourth pad electrodes formed on the principal surface thereof, and the third and fourth pad electrodes are connected to one another via the rewiring layer to form a short-circuit, and are not connected to any of the external terminals.
